(19) United States
(12) Patent Application Publication
(10) Pub. No.: US 2024/0410048 A1
(43) Pub. Date: Dec. 12, 2024

(54) METHOD FOR COATING A FLAT STEEL PRODUCT WITH LOW SUSCEPTIBILITY OF CRATERS IN THE PAINT

(71) Applicant: ThyssenKrupp Steel Europe AG, Duisburg (DE)

(72) Inventor: Stefan BIENHOLZ, Bochum (DE)

(73) Assignee: ThyssenKrupp Steel Europe AG, Duisburg (DE)

(21) Appl. No.: 18/702,179

(22) PCT Filed: Oct. 11, 2022
(86) PCT No.: PCT/EP2022/078287

§ 371 Date: Apr. 17, 2024

(30) Foreign Application Priority Data
Oct. 19, 2021 (DE) 10 2021 127 116.9

(51) Int. Cl. C23C 14/16; C22C 38/00; C22C 38/02; C22C 38/04; C22C 38/06; C22C 38/42; C22C 38/44; C22C 38/46; C22C 38/48; C22C 38/50; C22C 38/54; C23C 14/02; C23C 14/32

(52) U.S. Cl. CPC C23C 14/16; C22C 38/001; C22C 38/002; C22C 38/004; C22C 38/008; C22C 38/02; C22C 38/04; C22C 38/06; C22C 38/42; C22C 38/44; C22C 38/46; C22C 38/48; C22C 38/50; C22C 38/54; C23C 14/021; C23C 14/325

(57) ABSTRACT

The present disclosure relates to a method of producing a coated flat steel product. The method includes; producing or providing a steel substrate; optionally degreasing; optionally deoxidizing; and applying an anticorrosion coating. The anticorrosion coating is composed of zinc or a zinc alloy and unavoidable impurities by physical vapor phase deposition to the steel substrate having a substrate temperature. The method includes subjecting the steel substrate to a vacuum treatment for a particular period of time prior to the applying of the anticorrosion coating. Moreover, the pressure on application of the anticorrosion coating is suitably limited.

The automotive industry, especially in the case of visible components, puts great value on a high surface quality. A typical example of this is the outer skin of an automobile. In the case of the outer skin, customers put particular value on a good impression given by the paint, and so the surface of the flat steel product used has to be virtually free of defects. Such flat steel products are typically first provided electrolytically with an anticorrosion coating composed of zinc or a zinc alloy and then painted by cathodic electrocoating.

“Flat steel products” in the present text are understood to mean rolled products having significantly greater length and width than their thickness. These especially include steel strips and steel sheets or blanks.

However, this production method has some drawbacks. For instance, it is a common problem that further processing results in local coating defects, for example paint craters in cathodic electrocoating. Such coating defects arise at those sites on the flat steel product where there were already surface defects on the flat steel product prior to coating with an anticorrosion coating. Such surface defects correspond to the discontinuities of flat steel products for process-related reasons, meaning that the surface defects typically include near-surface steel dislocations that are only partly connected to the steel matrix, like “flaps”, or flaky metal resulting from opened-up cracks where there is a cavity open on one side immediately beneath the surface. Such defects arise predominantly from the manufacturing steps in the hot rolling, cold rolling and pickling plants. For example, the defects may be rolled-over pickling pores. In the subsequent cathodic electrocoating, these surface defects can lead to paint defects, especially paint craters (e.g. blisters, holes, pustules, pinpricks). These surface defects are problematic especially in that they are not immediately apparent on the coated flat steel product. It is therefore necessary to conduct a laborious approval test where random samples are painted for testing purposes and examined for paint defects. In spite of this random sampling, the risk remains that defective flat steel products will be delivered and will lead to high costs as a result of customer complaints.

It is therefore an object of the present invention to provide a coating method in order to provide flat steel products with an anticorrosion coating that reduces propensity to paint craters in the subsequent painting operation.

This object is achieved by a method of producing a coated flat steel product, having the following steps:
producing or providing a steel substrate
optionally degreasing
optionally deoxidizing
applying the anticorrosion coating composed of zinc or a zinc alloy and unavoidable impurities by physical vapor phase deposition to the steel substrate having a substrate temperature T_{substrate},
   wherein the steel substrate, prior to the applying of the anticorrosion coating, is subjected to a vacuum treatment for a duration t_{vacuum} for which:

$${t}_{vacuum} \geq max ( 4 s ; 24 - 0.2 \frac{s}{° C .} \cdot {T}_{substrate} )$$

and wherein a pressure on applying the anticorrosion coating is not more than a maximum process pressure Pₘₐₓ for which:

$${P}_{max} = 1. \frac{mbar}{{( ° C . )}^{2}} {( \frac{{T}_{substrate}}{6} )}^{2}$$

In the context of this application, what is meant by an “anticorrosion coating composed of zinc” is an anticorrosion coating which, aside from zinc, contains merely unavoidable impurities, i.e. consists of zinc and unavoidable impurities.

In the context of this application, what is meant by an “anticorrosion coating composed of a zinc alloy” is an anticorrosion coating consisting of not more than 50% by weight of further alloy elements, the balance being zinc and unavoidable impurities.

More preferably, such an anticorrosion coating consists of not more than 40% by weight, especially not more than 30% by weight, preferably not more than 10% by weight, of further alloy elements, the balance being zinc and unavoidable impurities.

The further alloy elements are preferably selected from the group of aluminum, alkaline earth metals, semimetals.

A proportion of further alloy elements in % by weight should be regarded as the sum total of the percentages by weight of all further alloy elements.

“Unavoidable impurities” in a steel, zinc or other alloy in the present text refer to technically unavoidable accompanying substances that get into the steel or coating in the course of production or cannot be fully removed, but the contents of which are in any case so small that they have no effect on the properties of the steel or coating.

In the present text, unless explicitly stated otherwise, figures for the contents of alloy constituents (for example the zinc alloy) are always given in % by weight (% by wt.).

Studies have shown that the paint defects in the subsequent cathodic electrocoating arise essentially from two mechanisms. Firstly, diffusible hydrogen in the steel substrate can recombine to give molecular hydrogen in the near-surface cavities in the course of baking of the electrocoating (about 200° C.). This leads to a rise in pressure in the cavity and hence ultimately to yielding of the anticorrosion coating and of the paint above the trapped volume of hydrogen. The escape of the gas gives rise to an unwanted paint defect. Secondly, residues of liquid (for example residues of acid from pickling operations) or gases can collect in the cavities, which evaporate or expand on baking and hence likewise generate an elevated pressure that ultimately leads to yielding of the anticorrosion coating and of the paint above the cavity. Here too, the escaping of the evaporated liquid gives rise to an unwanted paint defect.

The method of the invention reduces both effects. Fundamentally, coating methods by means of physical vapour deposition (PVD) do not lead to excessive introduction of hydrogen into the steel substrate, by contrast with electrolytic coating methods. In electrolytic coating methods, by contrast, hydrogen will always form at the surface to be coated at industrially relevant coating rates.

The vacuum treatment of the invention for a period of at least t_{vacuum} prior to the applying of the anticorrosion coating additionally ensures that any liquid residues can outgas prior to the coating. Measurements have shown that a shorter vacuum treatment is generally sufficient at higher substrate temperatures than at lower substrate temperatures, but the vacuum treatment must in any case last for at least 4 s in order to ensure sufficient outgassing of the cavities in the case of the typical surface defects in steel production. The vacuum treatment must thus last at least for 4 s and at least for a period of

$$24 - 0.2 \frac{s}{° C .} \cdot {T}_{substrate} .$$

Thus, the duration t_{vacuum} for the vacuum treatment is limited by the maximum of the two parameters:

$${t}_{vacuum} \geq max ( 4 s ; 24 - 0.2 \frac{s}{° C .} \cdot {T}_{substrate} )$$

What is meant by max(a;b) is the maximum of the two values a and b. The result of the formula max(a;b) is thus a when a>b, or b when b>a. When a=b, the result of max(a;b)=a=b.

What is meant by a vacuum treatment in the context of this application is the holding of the steel substrate for a duration in an environment at a pressure of less than 800 mbar; in particular the pressure is not more than 500 mbar, preferably not more than 200 mbar.

In a preferred variant, t_{vacuum} for the vacuum treatment is not more than 3 minutes. It has been found that no significant outgassing occurs after this duration.

In a further-preferred variant, a degree of ionization a during the vacuum treatment is not more than 0.1, preferably not more than 0.01, more preferably not more than 0.001. The degree of ionization during the vacuum treatment is defined here as the ratio of the density of ionized to neutral particles in the residual gas from the vacuum:

$$α = \frac{{n}^{+}}{n}$$

with the ion density n⁺ and the neutral particle density n. This low ion content ensures that ion bombardment of the surface to be coated remains limited.

The steel substrate may optionally be introduced into the vacuum already having been brought to the substrate temperature, or may be heated to the substrate temperature in the vacuum. In the latter case, the duration t_{vacuum} means the time in the vacuum after the attainment of the substrate temperature (i.e. without the time for the heating to the substrate temperature).

In addition, it has to be ensured that the cavities in the applying of the anticorrosion coating that directly follows the vacuum treatment remain largely free of gas. This is ensured in that the pressure in the applying of the anticorrosion coating is not more than a maximum process pressure Pₘₐₓ for which:

$${P}_{max} = 1. \frac{mbar}{{( ° C . )}^{2}} {( \frac{{T}_{substrate}}{6} )}^{2}$$

In a preferred development of the method, the duration is at least 6 s or at least

$$24 - 0.15 \frac{s}{° C .} \cdot {T}_{substrate} .$$

More preferably, the duration is at least 6 s and at least

$$24 - 0.15 \frac{s}{° C .} \cdot {T}_{substrate}$$

and so, for the duration t_{vacuum}:

$${t}_{vacuum} \geq max ( 6 s ; 24 - 0.15 \frac{s}{° C .} \cdot {T}_{substrate} ) .$$

This in particular assures sufficient outgassing of the cavities.

In an alternative or supplementary preferred development, the pressure in the applying of the anticorrosion coating is not more than

$${P}_{max} = 0.6 \frac{mbar}{{( ° C . )}^{2}} {( \frac{{T}_{substrate}}{6} )}^{2} .$$

This ensures with particular certainty that the cavities remain largely free of gas.

In a developed variant of the method, the temperature of the steel substrate on applying the anticorrosion coating is greater than 50° C., especially greater than 80° C., preferably greater than 100° C. Further preferably, the temperature of the steel substrate on applying the anticorrosion coating is less than 300° C. This enables procedurally reliable condensation of the coating material.

In a preferred execution variant, the anticorrosion coating has been applied by physical vapor deposition (PVD). It has been found that the surface structure of the invention can be achieved in a simple manner in this way.

In the inventive applying of the anticorrosion coating by physical vapor deposition, a coating material which is in initially solid or liquid form is applied by physical processes. This can be done, for example, thermally by directly heating the coating material (for example via an electrical arc), by bombardment with an electron beam or ion beam, or by exposure to a laser beam. Preference is given to evaporation by electrical arc, since this enables higher coating rates that make industrial use more efficient.

In order that the vapor particles of the evaporated coating material can reach the workpiece to be coated and are not lost to the coating through collision with gas particles in the ambient atmosphere, the method of PVD coating is conducted in a coating chamber under reduced pressure.

In a preferred embodiment, the anticorrosion coating composed of zinc or a zinc alloy is applied to the steel substrate by physical vapor deposition in that the steel substrate is adjusted to a substrate temperature and provided in a coating chamber, where the pressure in the coating chamber is regulated. This involves injection of zinc or a zinc alloy as coating material into the coating chamber at an injection site, where the zinc or zinc alloy is adjusted to a temperature.

In a preferred embodiment of the present invention, pressure and temperature are adjusted such that the temperature is above the dew point of the coating material. The coating material is in its gaseous phase at a temperature above its dew point. If the pressure is adjusted, for example increased, the dew point will shift, to higher temperatures in the example. Appropriate closed-loop control of the temperature ensures that the coating material is in gaseous form.

Further preferably, the vacuum treatment takes place immediately prior to the applying of the anticorrosion coating, such that the steel substrate is first adjusted to a substrate temperature T_{substrate} and then passes successively through a vacuum region and a coating chamber, where the vacuum treatment is conducted in the vacuum region and the application of the anticorrosion coating in the coating chamber. The steel substrate, between vacuum treatment and application of the anticorrosion coating, is subjected only to environments at a pressure of not higher than 120% of the average pressure in the vacuum treatment: in particular, the vacuum region and coating chamber are in direct succession (separated if appropriate merely by a pressure lock).

This ensures that the cavities cannot be filled again with too much gas between vacuum treatment and coating.

In a preferred configuration, the pressure on applying the anticorrosion coating is at least 1 mbar, preferably at least 5 mbar, more preferably at least 10 mbar, especially at least 20 mbar, preferably at least 40 mbar. Further preferably, the pressure on applying the anticorrosion coating is not more than 100 mbar, preferably not more than 80 mbar.

In a specific development, the application of the anticorrosion coating takes place in a protective gas atmosphere with a pressure between 1 mbar and 100 mbar, especially between 10 mbar and 100 mbar. The reduced pressure in the coating chamber is thus between 1 mbar and 100 mbar, especially between 10 mbar and 100 mbar. This ensures that less coating material is lost to the coating as a result of scatter by particles in the coating chamber. At the same time, the pressure is within a range achievable without an unreasonable burden in industrial scale use in industrial plants, for example in the coating of steel strips.

In a preferred development, the pressure in the vacuum treatment corresponds to the pressure on applying the anticorrosion coating. In this way, the steel substrate to be coated can be transferred directly from the vacuum region into the coating chamber without having to pass through a pressure lock. This can make the plant simpler since it is possible to dispense with a pressure lock.

In particular, the protective gas atmosphere has an oxygen content of less than 5% by volume, preferably less than 2% by volume, especially less than 1% by volume. This ensures that there is no unwanted oxidation of the hot steel substrate.

The protective gas atmosphere is preferably an inert gas atmosphere, especially a nitrogen atmosphere and/or an argon atmosphere, meaning that the protective gas atmosphere consists exclusively of an inert gas, especially nitrogen or argon or a mixture of nitrogen and argon and technically unavoidable impurities. Alternatively, the protective gas atmosphere is an inert gas atmosphere with added hydrogen. In that case, the protective gas atmosphere consists of up to 8% by volume of hydrogen, the balance being inert gas (especially nitrogen or argon or a mixture of nitrogen and argon) and technically unavoidable impurities.

In a preferred development, the coating rate on applying the anticorrosion coating is greater than 0.5 μm/s. In particular, the coating rate is at least 2 μm/s. Further preferably, the coating rate is not more than 100 μm/s, especially not more than 20 μm/s. It has been found that, at these coating rates, application of the anticorrosion coating is rapid and additionally simultaneously procedurally reliable.

In a preferred execution variant, the anticorrosion coating has a thickness of 1-20 μm, preferably 1-10 μm. More preferably, the thickness is 3-10 μm. In particular, the thickness is at least 5 μm. In addition, the thickness is in particular up to 8 μm. Layers below 1 μm typically do not offer sufficient corrosion protection. For typical automobile components made of flat steel products, with a layer thickness of 3 μm or more, sufficient corrosion protection is achieved up to the end of the product lifetime. Corrosion protection improves up to a thickness of 20 μm. Over and above that thickness, there is no further significant improvement. Moreover, excessively thick layers (greater than 20 μm) are not preferred because of the correspondingly longer coating time and higher material costs.

The ranges mentioned have been found to be a good compromise between sufficient corrosion protection and manufacturing costs, which rise with layer thickness.

The steel substrate of the flat steel product is preferably a carbon steel, especially with a carbon content of up to 0.5% by weight.

In a preferred development, the steel substrate has a tensile strength of not more than 600 MPa, especially not more than 500 MPa, and preferably a tensile strength of more than 200 MPa. The steel substrate is thus particularly pliable and in particular deep-drawable, and so it can be used particularly efficiently for outer skin applications with a high-quality appearance.

Mechanical properties such as tensile strength, yield point and elongation that are reported here have been ascertained in the tensile test according to DIN-EN ISO 6982-1, sample shape 2 (Annex B Tab. B1) (version of 2020-06), unless explicitly stated otherwise.

In a preferred configuration, the steel substrate is a ferritic steel, especially a ferritic steel having a ferrite content of more than 80% by volume.

In a specific preferred variant, the steel substrate is composed of a deep-drawing steel having the following analysis (figures in % by weight):
C: up to 0.20% by weight, preferably up to 0.18% by weight, especially to 0.12% by weight,
Si: up to 0.70% by weight, preferably up to 0.50% by weight, especially to 0.12% by weight,
Mn: 0.01% by weight-1.20% by weight, preferably up to 0.60% by weight,
   optionally one or more of the following elements:
P: up to 0.12% by weight, preferably up to 0.07% by weight, especially up to 0.05% by weight,
S: up to 0.05% by weight, preferably up to 0.03% by weight,
Al: 0.005% by weight-0.100% by weight,
Cr: up to 0.20% by weight, preferably up to 0.10% by weight,
Cu: up to 0.20% by weight, preferably up to 0.15% by weight,
Mo: up to 0.05% by weight, preferably up to 0.03% by weight,
N: up to 0.03% by weight, preferably up to 0.01% by weight,
Ni: up to 0.50% by weight, preferably up to 0.10% by weight,
Nb: up to 0.01% by weight, preferably up to 0.005% by weight,
Ti: up to 0.20% by weight, preferably up to 0.12% by weight,
V: up to 0.050% by weight, preferably up to 0.015% by weight,
B: up to 0.010% by weight, preferably up to 0.004% by weight,
Sn: up to 0.05% by weight, preferably up to 0.030% by weight,
Ca: up to 0.01% by weight, preferably up to 0.005% by weight,
   balance: iron and unavoidable impurities.

The invention is elucidated in detail by the working examples that follow.

By way of evidence of the invention, a special reject sample of a steel substrate having the composition given in table 1 with a ferritic microstructure was used.

The tensile strength of the steel substrate was 285 MPa.

The special reject sample was selected so as to result in a particularly large number of paint defects in a typical electrolytic zinc coating (layer thickness 7 μm) and subsequent cathodic electrocoating. In the specific case, there were reproducibly more than 500 000 paint defects in 6 square decimeters. This was tested by repeatedly dezincifying and recoating and painting the sample. In all electrolytic coating operations, there were consistently more than 500 000 paint defects in 6 square decimeters. This value was taken as reference in order to assess propensity to paint craters. If less than 1% of the paint defects were found by comparison with the above-described electrolytic reference sample in the case of the identical sample after coating and cathodic electrocoating, propensity to paint craters was assessed as “OK”. The identical sample was thus not to have more than 5000 paint craters in 6 square decimeters for the coating method employed to be regarded as being in accordance with the invention.

Specifically, the experiments were conducted by first phosphating the respective zinc layer in a known manner and then providing it with a cathodic electrocoating of paint thickness 20±0.6 μm according to DIN EN ISO 2178 2016-11.

Table 2 below shows propensity to paint craters by the assessment method described above for various coating variants. What are reported in each case are the pressure on applying the anticorrosion coating, the substrate temperature T_{substrate} and the duration of vacuum treatment t_{vacuum}. The experiments were each conducted with a plant without a lock between the vacuum treatment and the coating. The vacuum treatment pressure thus corresponds to the reported pressure in the applying of the anticorrosion coating. If the number of paint craters is less than 1% of the number of paint craters in the electrolytically coated comparative sample, propensity to paint craters was assessed as “OK”, otherwise as “not OK”.

TABLE 1

| C | Si | Mn | P | Al | Ti | S | Cr | Nb | V | Mo | N | Cu | Ni | B | S [symbol] |
|---|---|---|---|---|---|---|---|---|---|---|---|---|---|---|---|
| 0.0025 | 0.006 | 0.09 | 0.008 | 0.024 | 0.073 | 0.007 | 0.024 | 0.001 | 0.002 | 0.004 | 0.0037 | 0.010 | 0.016 | 0.0002 | 0 [symbol] |

Figures in % by weight, balance: iron and unavoidable impurities [symbol]
indicates data missing or illegible when filed

TABLE 2

| | | | | | | | | Layer | |
|---|---|---|---|---|---|---|---|---|---|
| | | | | | | Zn | | thickness of | |
| | | | | | Zr | coating | | cathodic | Propensity |
| | Coating | Pressure | T_{substrat} [symbol] | t_{vacuum} | thickness d | rate | | electrocoat | to paint |
| No. | method | [mbar] | [° C.] | [s] | [μm] | [μm/s] | Phosphation | [μm] | craters |
| 1 | arc | 60 | 120 | 6 | 7 | 8 | yes | 20 | OK |
| 2 | arc | 60 | 60 | 6 | 8 | 8 | yes | 21 | not OK |
| 3 | arc | 60 | 60 | 15 | 7 | 8 | yes | 19 | OK |
| 4 | arc | 60 | 20 | 6 | 6 | 8 | yes | 20 | not OK |
| 5 | arc | 60 | 120 | 3 | 7 | 8 | yes | 19 | not OK |
| 6 | electron | 0.005 | 20 | 30 | 7 | 0.01 | yes | 19 | OK |
| | beam | | | | | | | | |
| 7 | electron | 0.1 | 20 | 30 | 8 | 0.01 | yes | 20 | OK |
| | beam | | | | | | | | |

[symbol]

indicates data missing or illegible when filed

1-11. (canceled)

12. A method of producing a coated flat steel product, the method comprising:
providing a steel substrate; and
applying an anticorrosion coating composed of zinc or a zinc alloy and unavoidable impurities by physical vapor phase deposition to the steel substrate having a substrate temperature T_{substrate},
wherein the steel substrate, prior to the applying of the anticorrosion coating, is subjected to a vacuum treatment for a duration t_{vacuum} for which:
$${t}_{vacuum} \geq max ( 4 s ; 24 - 0.2 \frac{s}{° C .} \cdot {T}_{substrate} )$$
and a pressure on applying the anticorrosion coating is not more than a maximum process pressure Pₘₐₓ for which:
$${P}_{max} = 1. \frac{mbar}{{( ° C . )}^{2}} {( \frac{{T}_{substrate}}{6} )}^{2}$$

13. The method as claimed in claim 12, wherein for the duration t_{vacuum}:
$${t}_{vacuum} \geq max ( 6 s ; 24 - 0.15 \frac{s}{° C .} \cdot {T}_{substrate} )$$

14. The method as claimed in claim 12 wherein the pressure on applying the anticorrosion coating is not more than
$${P}_{max} = 0.6 \frac{mbar}{( ° C . )} {( \frac{{T}_{substrate}}{6} )}^{2} .$$

15. The method as claimed in claim 12 wherein the pressure on applying the anticorrosion coating is at least 1 mbar, preferably at least 5 mbar.

16. The method as claimed in claim 15 wherein the substrate temperature on applying the anticorrosion coating is greater than 100° C.

17. The method as claimed in claim 12 wherein the anticorrosion coating composed of zinc or a zinc alloy and unavoidable impurities is applied to the steel substrate by physical vapor deposition in that the steel substrate is adjusted to a substrate temperature and provided in a coating chamber, where the pressure in the coating chamber is regulated and where zinc or a zinc alloy as coating material is injected into the coating chamber at an injection site, where the zinc or zinc alloy is adjusted to a temperature.

18. The method as claimed in claim 12 wherein the applying of the anticorrosion coating takes place in a protective gas atmosphere with an oxygen content of less than 5% by volume.

19. The method as claimed in claim 12 wherein the coating rate of application of the anticorrosion coating is between 2 μm/s and 20 μm/s.

20. The method as claimed in claim 19 wherein the anticorrosion coating has a thickness d of 5-10 μm.

21. The method as claimed in claim 19 wherein the steel substrate has a tensile strength of not more than 500 MPa, and a tensile strength of more than 200 MPa.

22. The method as claimed in claim 21 wherein the steel substrate is a ferritic steel, having a ferrite content of more than 80% by volume.

23. The method of claim 12, further comprising:
degreasing the steel substrate.

24. The method of claim 12, further comprising:
deoxidizing the steel substrate.
